(19) United States
(12) Patent Application Publication
(10) Pub. No.: US 2019/0144993 A1
(43) Pub. Date: May 16, 2019

(54) METAL PARTS AND METHOD FOR MANUFACTURING SAME AND PROCESS CHAMBER PROVIDED WITH METAL PARTS

(71) Applicant: ABM CO., LTD., Asan (KR)

(72) Inventors: Bum Mo AHN, Suwon (KR); Seung Ho PARK, Hwaseong (KR)

(21) Appl. No.: 16/088,792

(22) PCT Filed: Mar. 20, 2017
(86) PCT No.: PCT/KR2017/002921

§ 371 Date: Sep. 26, 2018

(30) Foreign Application Priority Data
Mar. 31, 2016 (KR) 10-2016-0039257

(51) Int. Cl. C23C 16/44; C25D 11/10; C25D 11/12; C25D 11/24

(52) U.S. Cl. CPC C23C 16/44; C25D 11/10; C25D 21/12; C25D 11/24; C25D 11/12

(57) ABSTRACT

The present invention relates to a metal part and a process chamber having the metal part and, more particularly, to a metal part and a process chamber provided with the same, the metal part enabling a process failure and a production yield decrease of a display or a semiconductor to be prevented by forming a hole-free anodization barrier layer on the surface of a metal part used in a display or semiconductor manufacturing process and a process chamber having the same.

### TECHNICAL FIELD

The present invention relates to a metal part, a method of manufacturing the same, and a process chamber provided with the same. More particularly, the present invention relates to a metal part, a method of manufacturing the same, and a process chamber provided with the same, the metal part constituting a process chamber, which is used for manufacturing a display or a semiconductor, and an inner surface of the process chamber or being installed as an inner part therein.

### BACKGROUND ART

A chemical vapor deposition (CVD) apparatus, a physical vapor deposition (PVD) apparatus, a dry etching apparatus, and the like (hereinafter, referred to as a process chamber) use reaction gas, etching gas, or cleaning gas (hereinafter, referred to as process gas) inside the process chamber. Corrosive gases such as Cl, F, and Br are mainly used as the process gas such that significant corrosion resistance is required.

Accordingly, there is a conventional technique using stainless steel as apart for a process chamber. However, stainless steel does not have sufficient thermal conductivity and heavy metals such as Cr and Ni, which are alloy components of the stainless steel, may be released during a process such that surroundings are contaminated.

Therefore, aluminum or aluminum alloy parts of a process chamber have been developed which are lighter than stainless steel, have excellent thermal conductivity, and cause no heavy metal contamination. However, surfaces of aluminum and aluminum alloy have poor corrosion resistance and thus methods for surface treatment of the surfaces have been studied.

For example, as shown in FIG. 1, an anodic oxide film 20 having pores is formed to improve corrosion resistance and breakdown voltage properties of aluminum or an aluminum alloy, the anodic oxide film 20 including a porous layer 42 in which multiple pores 43 are formed by anodizing a surface of aluminum 10 and a barrier layer 41 having no pores 43. Unlike the porous layer 42, the barrier layer 41 of the anodic oxide film 20 has no pores. In the conventional anodic oxide film 20, a thickness of the barrier layer 41 is less than several tens of nm, but the porous layer 42 is configured to have a thickness of several tens of μm to several hundreds of μm for the breakdown voltage properties.

The conventional anodic oxide film 20 in which a majority of the thickness thereof is the thickness of the porous layer 42 has problems that the anodic oxide film is cracked due to a change in internal stress or due to thermal expansion whereby the anodic oxide film 20 peels off. Accordingly, the exposed aluminum or aluminum alloy functions as a lightning rod, and a plasma arc is generated in which plasma is concentrated at the exposed aluminum part instantaneously such that the aluminum surface is partially melted or fractured.

In addition, in forming the porous layer 42 of the anodic oxide film 20, foreign substances deposited inside the pores 43 of the porous layer 42 are gasified such that particles are formed on a substrate or fluoride used during the process remains in the pores 43. Then, when using the process chamber again, the particles fall on a substrate surface, leading to defects in process, a decrease of production yield, and shortening of a maintenance cycle of the process chamber.

Due to the problems of the porous layer 42 of the anodic oxide film 20, a method of using a part of aluminum or aluminum alloy that is not anodized (bare aluminum or bare aluminum alloy) has recently been developed. However, in the case of the bare aluminum part or bare aluminum alloy part, process gas and the aluminum react chemically, leading to generation of aluminum fumes such that particles are generated on a substrate of a semiconductor element or a liquid crystal display element.

### DISCLOSURE

### Technical Problem

Accordingly, the present invention has been made keeping in mind the above problems occurring in the related art, and an object of the present invention is to provide a metal part, a method of manufacturing the same, and a process chamber provided with the same, the metal part having excellent corrosion resistance, breakdown voltage properties, and plasma resistance compared with a metal base material and being provided with a surface nano oxidation (SNO) film, thus preventing problems caused by pores 43 of a porous layer of a conventional anodic oxide film having pores.

### Technical Solution

In order to achieve the above object, according to one aspect of the present invention, there is provided a metal part provided inside a process chamber into which process gas flows, the metal part including: a base material of metal; and a surface nano oxidation (SNO) film formed on a surface of the base material, wherein the SNO film is formed by anodizing the base material, and includes a first anodic oxide film having a porous layer and a second anodic oxide film formed in pores of the first anodic oxide film such that a surface and the inside of the SNO film are not provided with pores.

In addition, the base material may be aluminum and the SNO film may be anodized aluminum oxide (Al₂O₃), which is formed by anodizing the aluminum.

In addition, a depth of the pores of the porous layer of the first anodic oxide film may be the same as a thickness of the second anodic oxide film.

In addition, the SNO film may be formed on the entire surface of the base material in a substantially uniform thickness.

In addition, the SNO film may have a thickness in a range of equal to or greater than 100 nm and less than 1 μm.

In addition, the process chamber may be a chemical vapor deposition (CVD) process chamber, and the metal part may constitute an inner surface of the CVD process chamber or may be installed as an inner part.

In addition, the metal part installed as the inner part may be at least one of a diffuser, a backing plate, a shadow frame, and a susceptor.

In addition, the process chamber may be a dry etching process chamber, and the metal part may constitute an inner surface of the dry etching process chamber or may be installed as an inner part.

Furthermore, the metal part installed as the inner part may be at least one of a bottom electrode, an electrostatic chuck of the bottom electrode, a baffle of the bottom electrode, an upper electrode, and a wall liner.

According to another aspect of the present invention, there is provided a method of manufacturing a metal part provided inside a process chamber into which process gas flows is provided, the method including: forming an SNO film in which a surface and the inside thereof have no pores by anodizing a surface of a metal base, wherein the forming of the SNO film includes: forming a first anodic oxide film to have a porous layer by anodizing in a first electrolyte solution; and forming a second anodic oxide film in pores of the porous layer of the first anodic oxide film by re-anodizing in a second electrolyte solution.

In addition, the first electrolyte solution may be oxalic acid and the second electrolyte solution may be citric acid.

Furthermore, a voltage may be 100 V to 500 V at the forming of the second anodic oxide film.

According to still another aspect of the present invention, there is provided a process chamber, the process chamber including a metal part constituting an inner surface of the process chamber or being provided as an inner part constituting the process chamber, the metal part including a base material of metal, a first anodic oxide film formed on a surface of the metal base, and a second anodic oxide film formed in pores of a porous layer of the first anodic oxide film such that an SNO film is provided, wherein process gas is introduced into the process chamber.

In addition, the base material may be aluminum and the SNO film may be anodized aluminum oxide (Al2O3), which is formed by anodizing the aluminum.

In addition, the base material may be provided with a through-hole extending through the base material from top to bottom, and the SNO film may be formed on the through-hole.

In addition, the SNO film may be formed on the entire surface of the base material in a substantially uniform thickness.

In addition, the SNO film may have a thickness in a range of equal to or greater than 100 nm and less than 1 μm.

The process chamber may be a CVD process chamber.

The CVD process chamber may include: a susceptor provided inside the CVD process chamber to support a substrate S; a backing plate provided at an upper portion of the CVD process chamber; a diffuser provided below the backing plate to supply process gas to the substrate S; and a shadow frame provided between the susceptor and the diffuser and covering an edge of the substrate S. At least one of the susceptor, the backing plate, the diffuser, and the shadow frame may be provided with the SNO film having no pores on a surface and the inside of a base material thereof.

In addition, the process chamber may be a dry etching process chamber.

The dry etching process chamber may include: a bottom electrode 220 provided inside the chamber to support a substrate S; an upper electrode provided above the bottom electrode and supplying process gas to the substrate S; and a wall liner provided on an inner wall of the chamber 200. At least one of the upper electrode, the bottom electrode, and the wall liner may be provided with the SNO film having no pores on a surface and the inside of a base material thereof.

### Advantageous Effects

As described above, a surface nano oxidation (SNO) film having no pores 43 is formed on a metal base of a metal part such that it is possible to obtain excellent corrosion resistance, breakdown voltage properties, and plasma resistance and prevent problems caused by pores 43 of a porous layer of a conventional anodic oxide film having pores.

### DESCRIPTION OF DRAWINGS

FIG. 1 is a diagram illustrating an aluminum anodic oxide film having pores according to the related art;

FIG. 2 is a diagram illustrating a surface nano oxidation (SNO) film of a metal part according to an embodiment of the present invention;

FIG. 3 is a diagram illustrating a process in which an SNO film of a metal part is formed according to an embodiment of the present invention;

FIG. 4 is a diagram illustrating a chemical vapor deposition (CVD) chamber in which the metal part of FIG. 2 constitutes an inner surface of the chamber or is installed as an inner part; and

FIG. 5 is a diagram illustrating a dry etching process chamber in which the metal part of FIG. 2 constitutes an inner surface of the chamber or is installed as an inner part.

### MODE FOR INVENTION

Hereinafter, embodiments of the present invention will be described in detail with reference to the accompanying drawings. The above and other objects, features and advantages of the present invention will be more clearly understood from the following detailed description when taken in conjunction with the accompanying drawings. However, the present invention is not limited to the embodiments described herein and may be specified in other forms. The embodiments of the present invention are presented to make complete disclosure of the present invention and help those who are ordinarily skilled in the art best understand the invention. The scope of the invention is defined only by the claims. In the detailed description, the same reference numbers of the drawings refer to the same or equivalent parts of the present invention.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

It will be understood that, although the terms first, second, etc. may be used herein to describe various elements, these elements should not be limited by these terms. These terms are only used to distinguish one element, from another element. As used herein, the term “surface nano oxidation (SNO) film” is defined as an oxide film formed on a surface of a base material.

In addition, the embodiments of the present invention are described with reference to sectional views and/or plan views, which schematically illustrate ideal embodiments of the present invention. In the drawings, the thickness of layers and regions are exaggerated for effective description of the technical contents. Therefore, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Thus, the exemplified regions illustrated in the drawings are schematic in nature, and their shapes are not intended to illustrate the specified shape of a region of a device and are not intended to limit the scope of the present invention.

Hereinbelow, the embodiments of the present invention will be described in detail with reference to the accompanying drawings.

Wherever possible, the same reference numerals will be used throughout different embodiments and the description to refer to the same or like elements or parts. In addition, the configuration and operation already described in other embodiments will be omitted for convenience.

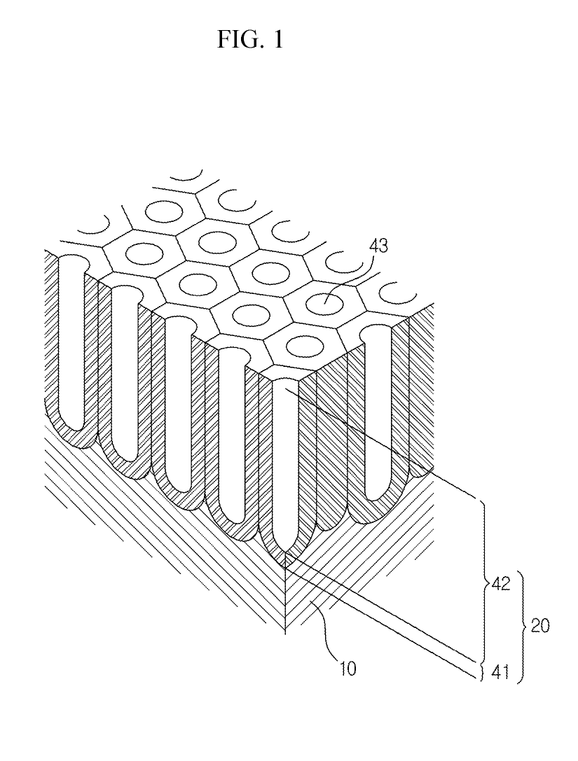

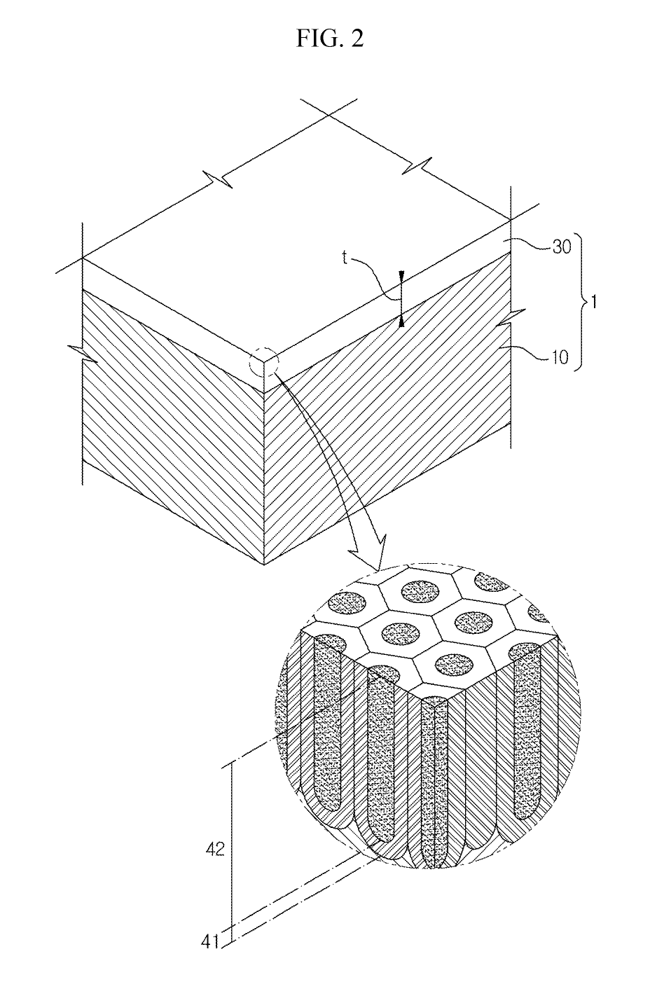

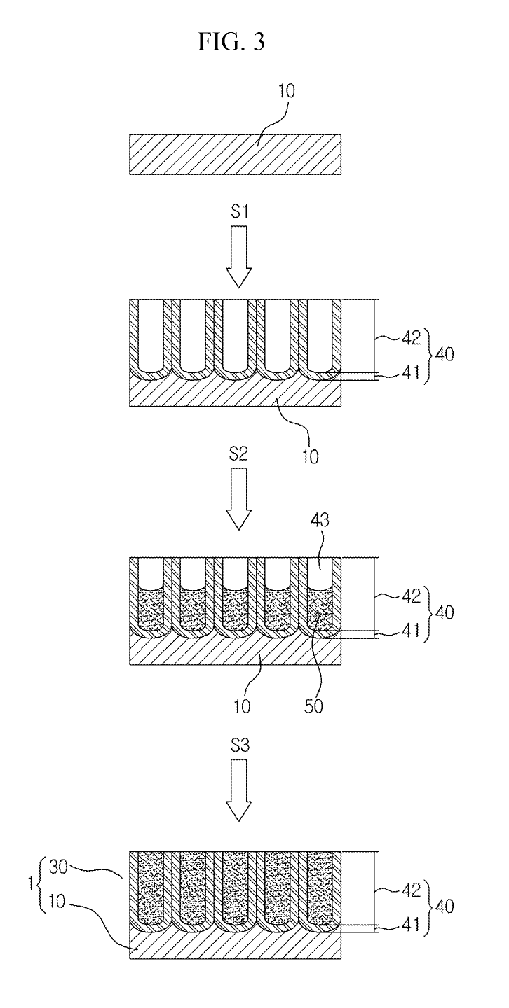

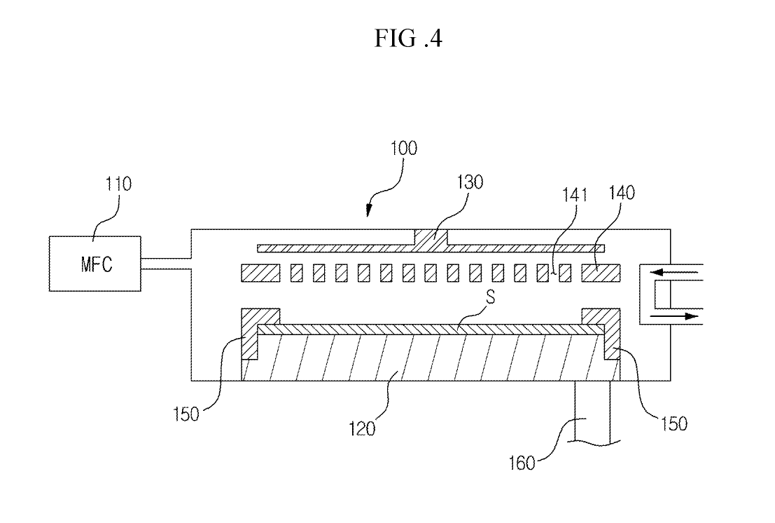

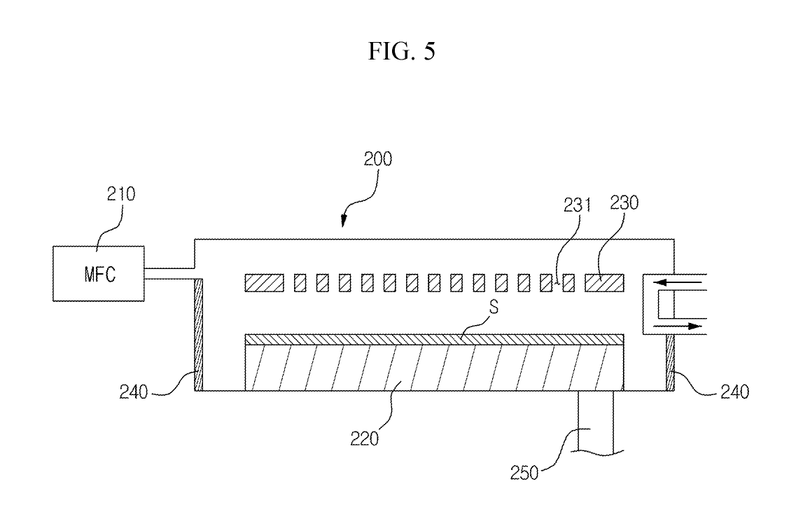

FIG. 1 is a diagram illustrating an aluminum anodic oxide film having pores according to the related art; FIG. 2 is a diagram illustrating a surface nano oxidation (SNO) film of a metal part according to an embodiment of the present invention; FIG. 3 is a diagram illustrating a process in which an SNO film of a metal part is formed according to an embodiment of the present invention; FIG. 4 is a diagram illustrating a chemical vapor deposition (CVD) chamber in which the metal part of FIG. 2 constitutes an inner surface of the chamber or is installed as an inner part; and FIG. 5 is a diagram illustrating an dry etching process chamber in which the metal part of FIG. 2 constitutes an inner surface of the chamber or is installed as an inner part.

A metal part 1 according to the embodiment of the present invention includes a base material of metal and a surface nano oxidation (SNO) film 30 formed on a surface of the base material without pores 43.

The SNO film 30 may be an anodic oxide film formed by anodizing the metal base.

The metal base may be made of one selected from the group consisting of aluminum (Al), titanium (Ti), tungsten (W), zinc (Zn), etc. The metal base may be made of aluminum or an aluminum alloy, which is lightweight, easy to process, excellent in thermal conductivity, and free from causing heavy metal contamination.

Here, the aluminum and the aluminum alloy according to the embodiment of the present invention include aluminum or an aluminum alloy in which the SNO film 30 is formed on the surface of the metal base by anodizing the aluminum or aluminum alloy. The description will be made only in the case where the metal base is aluminum 10.

As shown in FIG. 2, the metal part 1 according to the embodiment of the present invention includes aluminum 10 and the SNO film 30 formed in which a surface and the inside of the aluminum 10 have no pores 43.

The SNO film 30 is formed by anodizing the aluminum 10 and includes a first anodic oxide film 40 having pores 43 and a second anodic oxide film 50 formed in the pores 43 of the first anodic oxide film 40.

The first anodic oxide film 40 is formed by anodizing the aluminum 10 and is composed of aluminum oxide (Al₂O₃).

In addition, the first anodic oxide film 40 includes a barrier layer 41 and a porous layer 42 having the pores 43.

The second anodic oxide film 50 is grown whereby it fills the pores 43 of the porous layer 42 of the first anodic oxide film 40.

Thus, in this case, a thickness of the second anodic oxide film 50 is the same as a depth of the pores 43 of the porous layer 42 of the first anodic oxide film 40.

Because of the structure of the first anodic oxide film 40 and the second anodic oxide film 50, the SNO film 30 has a uniform thickness (t) throughout the entire surface of the aluminum 10, which is the base material, and the pores 43 are not provided on the surface and the inside of the SNO film 30.

That is, since the second anodic oxide film 50 is formed inside the pores 43 of the porous layer 42 of the first anodic oxide film 40, the surface and the inside of the SNO film 30 are not provided with the pores 43.

As described above, since the pores 43 are not provided on the surface of the SNO film 30, the structure of the SNO film 30 is dense such that permeation of process gas is impossible. As a result, since it is impossible for the process gas to permeate through the surface of the aluminum, excellent corrosion resistance to the process gas is obtained.

In addition, since the SNO film 30 has a sufficient thickness (t) and is composed of aluminum oxide (Al₂O₃), the SNO film 30 exhibits excellent corrosion resistance and has excellent breakdown voltage properties, due to the chemical characteristics of aluminum oxide (Al₂O₃). Furthermore, since the SNO film 30 does not have the pores 43 on the surface and the inside thereof, it is possible to prevent deposition and outgassing of foreign substances, which are conventionally caused by the porous layer of the conventional anodic oxide film.

Hereinafter, a method of manufacturing a metal part 1 in which an SNO film 30 is formed on a surface of aluminum 10 of the metal part 1 will be described according to an embodiment of the present invention with reference to FIG. 3.

The method of manufacturing the metal part 1 according to the embodiment of the present invention includes: forming a first anodic oxide film 40 to have a porous layer 42 by anodizing the surface of the aluminum 10 in a first electrolyte solution (S1); forming a second anodic oxide film 50 in pores 43 of the porous layer 42 of the first anodic oxide film 40 by re-anodizing in a second electrolyte solution (S2); and forming the SNO film 30 in which the second anodic oxide film 50 formed in the pores 43 of the porous layer 42 grows and fills the pores 43 of the porous layer 42 such that the SNO film 30 is not provided with the pores 43 (S3).

At the forming of the first anodic oxide film 40, the aluminum 10, which is a base material, is anodized in the first electrolyte solution such that the first anodic oxide film 40 having the barrier layer 41 and the porous layer 42 is formed on the surface of the aluminum 10.

Here, the first electrolyte solution used for anodizing at the forming of the first anodic oxide film 40 (S1) may be sulfuric acid (H₂SO₄), phosphoric acid, or the like. Preferably, the first electrolytic solution is oxalic acid (C₂H₂O₄) in the method of manufacturing the metal part 1 according to the embodiment of the present invention.

Accordingly, when releasing current into the aluminum 10 in an electrolytic bath with oxalic acid (C₂H₂O₄), the barrier layer 41 is formed on the surface of the aluminum 10.

Specifically, Al₃⁺ ions ionized from the aluminum 10 are introduced to the outside of the aluminum 10, and O₂⁻ ions and OH⁻ ions ionized from the oxalic acid electrolyte solution are introduced into the inside of the aluminum 10. Then, the Al₃⁺ ions and the O₂⁻ ions are coupled to each other by chemical reaction such that the barrier layer 41 is formed. Accordingly, the barrier layer 41 is formed in a structure not provided with the pores 43.

Thereafter, as the barrier layer 41 grows over time, the porous layer 42 is formed at an upper portion of the barrier layer 41 such that the porous layer 42 is formed to have the pores 43 unlike the barrier layer 41.

As described above, the forming of the first anodic oxide film 40 (S1) using oxalic acid (C₂H₂O₄) has the following process conditions based on 0.3 M of oxalic acid (C₂H₂O₄).

When performing the forming of the first anodic oxide film 40 (S1) using 0.3 M of oxalic acid (C₂H₂O₄), a voltage for causing conduction of a current through 0.3 M of oxalic acid (C₂H₂O₄) in the electrolytic bath with may be 40 V and the process may be carried out at a temperature of 5° C. to 40° C. In addition, the forming of the first anodic oxide film 40 (S1) using 0.3 M of oxalic acid (C₂H₂O₄) may be carried out for ten minutes.

Unlike the above, in case of performing the forming of the first anodic oxide film 40 (S1) using sulfuric acid (H₂SO₄) or phosphoric acid, which is not oxalic acid (C₂H₂O₄), the process conditions are given below.

When performing the forming of the first anodic oxide film 40 (S1) using 1.0 M of sulfuric acid (H₂SO₄), a voltage for causing conduction of a current through 1.0 M of sulfuric acid (H₂SO₄) in the electrolytic bath may be 20 V and the process may be carried out at a temperature of 0° C. In addition, the forming of the first anodic oxide film 40 (S1) using 1.0 M of sulfuric acid (H₂SO₄) may be carried out for ten minutes.

When performing the forming of the first anodic oxide film 40 (S1) using 1 wt % of phosphoric acid, a voltage for causing conduction of a current through 1 wt % of phosphoric acid in the electrolytic bath may be 195 V and the process may be carried out at a temperature of 10° C. In addition, the forming of the first anodic oxide film 40 (S1) using 1 wt % of phosphoric acid may be carried out for ten minutes.

After forming the first anodic oxide film 40, the second anodic oxide film 50 is formed (S2) in which the aluminum 10 provided with the first anodic oxide film 40 is re-anodized in the second electrolyte solution such that the second anodic oxide film 50 is formed in the pores 43 of the porous layer 42 of the first anodic oxide film 40.

Here, the second electrolyte solution used for re-anodizing at the forming of the second anodic oxide film 50 (S2) may be ammonium pentaborate octahydrate, DL-tartaric acid, adipic acid, sodium tungstate, ammonium adipate, sodium borate, or the like. Preferably, the second electrolytic solution is Citric Acid (C₆H₈O₇) in the method of manufacturing the metal part 1 according to the embodiment of the present invention.

Accordingly, when releasing current into the aluminum 10 provided with the first anodic oxide film 40 in an electrolytic bath with citric acid (C₆H₈O₇), the second anodic oxide film 50 grows to fill the pores 43 upwardly from a lower portion of the pores 43 of the porous layer 42 of the first anodic oxide film 40.

After performing the forming of the second anodic oxide film 50 (S2), the SNO film 30 is formed (S3) in which the second anodic oxide film 50 formed in the pores 43 of the porous layer 42 grows and fills the pores 43 of the porous layer 42 over time such that the SNO film 30 is not provided with the pores 43.

That is, after forming the second anodic oxide film 50 (S), as the second anodic oxide film 50 formed in the pores 43 of the porous layer 42 grows and fills the pores 43 of the porous layer 42 over time, the pores 43 of the porous layer 42 are completely clogged by the second anodic oxide film 50 such that the SNO film 30 in which the pores 43 are not provided on the surface and the inside thereof is formed on the surface of the aluminum 10.

In order to allow the second anodic oxide film 50 to entirely fill the pores 43 of the porous layer 42, voltages for causing conduction of a current through citric acid in the electrolytic bath may be 100 V to 500 V at the forming of the second anodic oxide film 50 (S2) and the forming of the SNO film 30 (S3).

As described above, the forming of the second anodic oxide film 50 (S2) using citric acid (C₆H₈O₇) has the following process conditions based on 0.02 M of citric acid (C₆H₈O₇).

When performing the forming of the second anodic oxide film 50 (S2) using 0.02 M of citric acid (C₆H₈O₇), a voltage for causing conduction of a current through 0.02 M of citric acid (C₆H₈O₇) in the electrolytic bath may be 300 V and the process may be carried out at a temperature of 10° C. In addition, the forming of the second anodic oxide film 50 (S2) using 0.02 M of citric acid (C₆H₈O₇) may be carried out for ten minutes.

The SNO film 30 of the metal part 1 manufactured through the above-described steps according to the embodiment of the present invention is not provided with a porous layer having pores 43, which means that the SNO film 30 has no pores 43 on the surface and the inside thereof.

In addition, the SNO film 30 is formed to have a predetermined thickness (t) to have sufficient corrosion resistance, breakdown voltage properties, and plasma resistance.

It is preferable that the SNO film 30 of the metal part 1 manufactured through the above-described steps according to the embodiment of the present invention has a thickness (t) of hundreds nm, and more preferably the SNO film 30 has a thickness (t) in a range of equal to or greater than 100 nm and less than 1 μm.

Removing of the first anodic oxide film 40 and re-forming of first anodic oxide film 40 may be further included between the forming of the first anodic oxide film 40 (S1) and the forming of the second anodic oxide film 50 (S2).

At the forming of the first anodic oxide film 40 (S1), the first anodic oxide film 40 formed at the forming of the first anodic oxide film 40 (S1) is removed. At the removing of the first anodic oxide film 40, the first anodic oxide film 40 is removed such that pores of the first anodic oxide film 40 to be formed at the re-forming of the first anodic oxide film 40 are aligned efficiently. Accordingly, when proceeding to the forming of the second anodic oxide film 50 (S2), it is possible to easily form the second anodic oxide film 50 in the pores 43 of the first anodic oxide film 40.

Here, a solution used at the removing of the first anodic oxide film 40 may be a mixed solution of 1.8 wt % of chromic acid (CrO₃) and 6 wt % of phosphoric acid (H₃PO₄).

As described above, the removing of the first anodic oxide film 40 using the mixed solution of 1.8 wt % of chromic acid (CrO₃) and 6 wt % of phosphoric acid (H₃PO₄) has the following process conditions.

The removing of the first anodic oxide film 40 using the mixed solution of 1.8 wt % of chromic acid (CrO₃) and 6 wt % of phosphoric acid (H₃PO₄) may be carried out at a temperature of 45° C. for 120 minutes.

At the re-forming of the first anodic oxide film 40, the first anodic oxide film 40 is formed on the aluminum 10 again after the above-mentioned removing of the first anodic oxide film 40 and a method and process conditions are the same as the above-mentioned forming of the first anodic oxide film 40 (S1). In other words, an electrolyte solution used at the above-mentioned forming of the first anodic oxide film 40 (S1) may be sulfuric acid (H₂SO₄), phosphoric acid, oxalic acid (C₂H₂O₄), or the like, and the first anodic oxide film 40 is re-formed under the process conditions described at the forming of the first anodic oxide film 40 (S1).

Hereinafter, a chemical vapor deposition (CVD) chamber 100 in which the above-mentioned metal part 1 of the embodiment of the present invention constitutes an inner surface of the process chamber or is installed as an inner part therein will be described with reference to FIG. 4.

As shown in FIG. 4, the CVD process chamber 100 includes: a mass flow controller (MFC) 110 provided outside the CVD process chamber 100; a susceptor 120 provided inside the CVD process chamber 100 to support a substrate S; a backing plate 130 provided at an upper portion of the CVD process chamber 100; a diffuser 140 provided below the backing plate 130 to supply process gas to the substrate S; and a shadow frame 150 provided between the susceptor 120 and the diffuser 140 and covering an edge of the substrate S.

The CVD process chamber 100 is provided with the susceptor 120, the backing plate 130, the diffuser 140, the shadow frame 150, and the like, and provides a reaction space for CVD process with the process gas to take place.

A process gas supply port (not shown) may be provided on the CVD process chamber 100, the process gas supply port communicating with the backing plate 130 to supply the process gas. In addition, an exhaust port 160 through which the process gas undergone the chemical vapor deposition is exhausted may be provided under the CVD process chamber 100.

The MFC 110 serves to control gases flowing inside the CVD process chamber 100, i.e., the process gas.

The susceptor 120 is provided at a lower portion of the inside of the CVD process chamber 100 to support the substrate S during CVD process.

The susceptor 120 may be provided with a heater (not shown) therein to heat the substrate S according to process conditions.

The backing plate 130 is provided at the upper portion of the CVD process chamber 100 to communicate with the process gas supply port and assists the diffuser 140 that will be described later to evenly spray the process gas supplied from the process gas supply port by guiding the process gas to flow to the diffuser 140.

The diffuser 140 is provided below the backing plate 130 in a manner facing the susceptor 120, and serves to evenly spray the process gas on the substrate S.

In addition, the diffuser 140 is provided with multiple through-holes 141 extending through the diffuser 140 from top to bottom.

The through-holes 141 may have an orifice shape whose upper diameter is larger than a lower diameter.

In addition, the through-holes 141 may be provided in a uniform distance being apart from each other over the entire area of the diffuser 140, whereby gas can be evenly sprayed on the entire area of the substrate S.

That is, the process gas supplied from the process gas supply port flows into the diffuser 140 through the backing plate 130, and then the process gas is evenly sprayed on the substrate S through the through-holes 141 of the diffuser 140.

The shadow frame 150 serves to prevent a thin film from being deposited on the edge of the substrate S and is disposed between the susceptor 120 and the diffuser 140.

Here, the shadow frame 150 may be fixed to a side surface of the CVD process chamber 100.

The base material of at least one of the susceptor 120, the backing plate 130, the diffuser 140, the shadow frame 150, the exhaust port 160, and an inner surface of the CVD process chamber 100 may be aluminum 10.

The substrate S used in the CVD process chamber 100 may be a wafer or a glass.

The CVD process chamber 100 having the above configuration performs CVD process on the substrate S in which the process gas supplied from the process gas supply port is introduced to the backing plate 130 and then sprayed on the substrate S through the through-holes 141 of the diffuser 140.

The process gas is in plasma state and corrosive. The inner surface of the CVD process chamber 100 and the parts installed inside the CVD process chamber 100 such as the susceptor 120, the backing plate 130, the diffuser 140, the shadow frame 150, the exhaust port 160, and the like come into contact with the process gas.

At least one inner surface of the CVD process chamber 100 according to the embodiment of the present invention and/or at least one surface of at least one part among the inner parts of the CVD process chamber 100 according to the embodiment of the present invention is provided with an SNO film 30 having no pores 43.

In the CVD process chamber 100, the SNO film 30 may be formed on the inner surface of the chamber 100 in which the process gas flows, and also formed on an inner surface of the exhaust port 160 provided below the CVD process chamber 100.

The diffuser 140 is provided with the through-holes 41 extending through the diffuser 140 from top to bottom and the process gas flows through the through-holes such that the SNO film 30 may be formed not only on the surface of the diffuser 140 but also on the through-holes 41.

As described above, the SNO film 30 having no pores is formed in a sufficient thickness on the inner surface of the CVD process chamber 100 and on the surfaces of the parts, thereby improving the corrosion resistance, the breakdown voltage properties, and the plasma resistance. Accordingly, the problems of outgas and particle generation caused by the conventional pores 43 are solved. In addition, the yield of the finished product manufactured by the process chamber is improved, the process efficiency of the process chamber 100 is improved, and the maintenance cycle is increased.

Hereinafter, a dry etching apparatus 200 in which the above-mentioned metal part 1 of the embodiment of the present invention constitutes an inner surface of the apparatus or is installed as an inner part therein will be described with reference to FIG. 5.

As shown in FIG. 5, the dry etching-process chamber 200 includes: an MFC 210 provided outside the chamber 200; a bottom electrode 220 provided inside the chamber 200 to support a substrate S; an upper electrode 230 provided above the bottom electrode 220 and supplying process gas to the substrate S; and a wall liner 240 provided on an inner wall of the chamber 200.

The dry etching process chamber 200 is provided with the bottom electrode 220, the upper electrode 230, and the wall liner 240, and the like, and provides a reaction space for dry etching with the process gas to take place.

A process gas supply port (not shown) may be provided on the dry etching process chamber 200, the process gas supply port supplying the process gas to the upper electrode 230, which will be described later. In addition, an exhaust port 250 through which the process gas undergone the dry etching process is exhausted may be provided under the dry etching process chamber 200.

The MFC 210 serves to control gases flowing inside the dry etching process chamber 200, i.e., the process gas.

The bottom electrode 220 is provided at a lower portion of the inside of the dry etching process chamber 200 to support the substrate S during dry etching process.

In addition, the bottom electrode 220 may be provided with an electrostatic chuck (ESC, not shown) minimizing generation of static electricity on the substrate S and with a baffle (not shown) keeping the flow of the process gas around the substrate S constant such that uniform etching is achieved on the substrate S.

The upper electrode 230 is provided to face the susceptor 120 provided at the lower portion of the dry etching process chamber 200, and serves to evenly spray the process gas on the substrate S.

In addition, the upper electrode 230 is provided with multiple through-holes 231 extending through the upper electrode 230 from top to bottom.

The through-holes 231 may have an orifice shape whose upper diameter is larger than a lower diameter.

In addition, the through-holes 231 may be provided in a uniform distance being apart from each other over the entire area of the upper electrode 230, whereby gas can be evenly sprayed on the entire area of the substrate S.

That is, the process gas supplied from the process gas supply port flows into the upper electrode 230, and then the process gas is evenly sprayed on the substrate S through the through-holes 231 of the upper electrode 230.

The wall liner 240 may be installed detachably on the inner wall of the dry etching process chamber 200 and serves to reduce contamination of the process chamber 200.

That is, when the dry etching process is performed for a long time such that the inside of the dry etching process chamber 200 is contaminated, the wall liner 240 is separated to clean or replaced with a new one whereby it is possible to make the inner environment of the apparatus 200 clean.

The base material of at least one of the bottom electrode 220, the ESC and the baffle of the bottom electrode 220, the upper electrode 230, the wall liner 240, the exhaust port 250, and the inner surface of the dry etching process chamber 200 may be aluminum 10.

In addition, the substrate S used in the dry etching process chamber 200 may be a wafer or a glass.

The dry etching process chamber 200 having the above configuration performs dry etching process on the substrate S in which the process gas supplied from the process gas supply port is introduced to the upper electrode 230 and then sprayed on the substrate S through the through-holes 231 of the diffuser 140.

The process gas is in plasma state and corrosive. The inner surface of the dry etching process chamber 200 and the parts installed inside the chamber 200 such as the bottom electrode 220, the ESC and the baffle of the bottom electrode 220, the upper electrode 230, the wall liner 240, the exhaust port 250, and the like come into contact with the process gas.

At least one inner surface of the dry etching process chamber 200 according to the embodiment of the present invention and/or at least one surface of at least one part among the inner parts of the dry etching process chamber 200 according to the embodiment of the present invention is provided with an SNO film 30 having no pores 43.

In the dry etching process chamber 200, the SNO film 30 may be formed on the inner surface of the CVD process chamber 100 in which the process gas flows, and also formed on an inner surface of the exhaust port 250 provided below the dry etching process chamber 200.

The SNO film 30 may be formed on each inner surface of the bottom electrode 220, the ESC and the baffle of the bottom electrode 220, and the wall liner 240. The SNO film 30 may be formed on a surface and the through-holes 231 of the upper electrode 230 together.

As described above, the SNO film 30 having no pores is formed in a sufficient thickness on the inner surface of the dry etching process chamber 200 and on the surfaces of the parts, thereby improving the corrosion resistance, the breakdown voltage properties, and the plasma resistance. Accordingly, the problems of outgas and particle generation caused by the conventional pores 43 are solved. In addition, the yield of the finished product manufactured by the process chamber 200 is improved, the process efficiency of the process chamber 200 is improved, and the maintenance cycle is increased.

On the other hand, as the SNO film 30 is formed on the metal part 1 constituting an inner surface of an apparatus or is installed as an inner part therein, the SNO film 30 of the embodiment of the present invention may also be formed on every part in which a base material is aluminum and constitutes an inner surface of an apparatus or is installed as an inner part therein, the part being exemplified by a shower head, a chamber gate, a chamber port, a cooling plate, a chamber air nozzle, etc.

As described above, the present invention has been described with reference to the preferred embodiments. However, those skilled in the art will appreciate that various modifications, additions and substitutions are possible, without departing from the scope and spirit of the invention as disclosed in the accompanying claims.

### DESCRIPTION OF REFERENCE NUMERALS IN THE DRAWINGS

1: metal part
10: aluminum
20: anodic oxide film having pores
30: surface nano oxidation film
40: first anodic oxide film
41: barrier layer
42: porous layer
43: pores
50: second anodic oxide film
100: CVD process chamber
111, 210: mass flow controller
120: susceptor
130: backing plate
140: diffuser
141, 231: through-holes
150: shadow frame
160, 250: exhaust port
200: dry etching process chamber
220: bottom electrode
230: upper electrode
240: wall liner
S: substrate

1. A metal part provided inside a process chamber into which process gas flows, the metal part comprising:
a base material of metal; and
a surface nano oxidation (SNO) film formed on a surface of the base material,
wherein the SNO film is formed by anodizing the base material, and includes a first anodic oxide film having a porous layer and a second anodic oxide film formed in pores of the first anodic oxide film such that a surface and the inside of the SNO film are not provided with pores.

2. The metal part of claim 1, wherein the base material is aluminum and the SNO film is anodized aluminum oxide (Al₂O₃), which is formed by anodizing the aluminum.

3. The metal part of claim 1, wherein a depth of the pores of the porous layer of the first anodic oxide film is the same as a thickness of the second anodic oxide film.

4. The metal part of claim 1, wherein the process chamber is a chemical vapor deposition (CVD) process chamber, and
the metal part constitutes an inner surface of the CVD process chamber or is installed as an inner part.

5. The metal part of claim 4, wherein the metal part installed as the inner part is at least one of a diffuser, a backing plate, a shadow frame, and a susceptor.

6. The metal part of claim 1, wherein the process chamber is a dry etching process chamber, and
the metal part constitutes an inner surface of the dry etching process chamber or is installed as an inner part.

7. The metal part of claim 6, wherein the metal part installed as the inner part is at least one of a bottom electrode, an electrostatic chuck of the bottom electrode, a baffle of the bottom electrode, an upper electrode, and a wall liner.

8. A method of manufacturing a metal part provided inside a process chamber into which process gas flows, the method comprising:
forming an SNO film in which a surface and the inside thereof have no pores by anodizing a surface of a metal base,
wherein the forming of the SNO film includes:
forming a first anodic oxide film to have a porous layer by anodizing in a first electrolyte solution; and
forming a second anodic oxide film in pores of the porous layer of the first anodic oxide film by re-anodizing in a second electrolyte solution.

9. The method of claim 8, wherein the first electrolyte solution is oxalic acid and the second electrolyte solution is citric acid.

10. A process chamber comprising a metal part constituting an inner surface of the process chamber or being provided as an inner part constituting the process chamber, the metal part including a base material of metal and an anodic oxide film formed on a surface of the metal base such that an SNO film is provided,
wherein process gas is introduced into the process chamber.

11. The method of claim 10, wherein the base material is provided with a through-hole extending through the base material, and
the SNO film is formed on the through-hole.
